(19) United States
(12) Patent Application Publication
(10) Pub. No.: US 2008/0013581 A1
(43) Pub. Date: Jan. 17, 2008

(54) LOW OPTICAL FEEDBACK NOISE SELF-PULSATING SEMICONDUCTOR LASER

(75) Inventor: Masahide KOBAYASHI, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, Kawasaki (JP)

(21) Appl. No.: 11/775,989

(22) Filed: Jul. 11, 2007

(30) Foreign Application Priority Data
Jul. 11, 2006 (JP) 2006-190211

(51) Int. Cl. H01S 5/343; H01S 5/00

(52) U.S. Cl. 372/45.013

(57) ABSTRACT

A self-pulsating semiconductor laser includes a lower clad layer formed on a semiconductor substrate, an active layer formed on the lower clad layer, the first upper clad layer formed on the active layer, a second upper clad layer formed on the first upper clad layer and a block layers. The second upper clad layer has a mesa structure. The block layers are formed on both sides of the second upper clad layer and includes a layer the bandgap thereof is larger than that of the active layer. When a self-pulsation is performed, saturable absorber regions are formed on the both sides of a gain region. The thickness d of the first upper clad layer satisfies a relation 220 nm≦d≦450 nm. A stable self-pulsation can be achieved in a wide temperature range.

### BACKGROUND OF THE INVENTION

1. Field of the Invention

The present invention relates to a semiconductor laser and a manufacturing method thereof. More specifically, the present invention relates to a self-pulsating semiconductor laser that is excellent in suppressing an optical feedback noise, and to a manufacturing method thereof.

2. Description of Related Art

The semiconductor laser is used for light sources in optical disk devices, optical fiber communications, optical arithmetic operations and the like. In a case of an optical disk device such as a DVD device, there is possibility that reflected light from an optical disk makes incident again back on the semiconductor laser element. The light making incident back again on the element is called as feedback light, and a noise generated in the output of the emission light because of the feedback light is called an optical feedback noise. The optical feedback noise causes a signal readout error and the like. Therefore, it is one of the critical issues in the field of semiconductor lasers to suppress the optical feedback noise.

For reducing the optical feedback noise, it is necessary to weaken coherence of laser beams through making longitudinal mode of laser into multi-modes and applying wavelength chirping by fluctuating the refractive index of an active layer. As a method used therefore, there is known a method which superimposes a high-frequency electric current of several hundreds MHz to several GHz on a laser drive current (which is a direct current). In this case, a high-frequency oscillator is required additionally, thereby increasing the cost. Further, an unnecessary radiation (EMI: Electro-Magnetic Interference) is generated since the high-frequency current is used. To mount a component as a measure for dealing with EMI causes more increase in the cost.

Therefore, the “self-pulsating semiconductor laser” is attracting attentions as an alternative technique for suppressing the optical feedback noise. In the self-pulsating semiconductor laser, a region called the “saturable absorber” is provided in the vicinity of an active layer. The saturable absorber has a function of switching absorption/transmission of laser beams, and the intensity of the laser beams is automatically changed within a range between frequencies of several hundreds MHz to several GHz by the saturable absorber. That is, a self-pulsation is achieved thereby, and the same effect as a case of superimposing a high-frequency current can be obtained only with the element itself.

Some techniques related to the self-pulsating semiconductor laser are explained below.

In a self-pulsating semiconductor laser described in a Japanese Laid-Open Patent Application (JP-A-Heisei, 4-154184), a double heterostructure is formed on a first conductivity type GaAs substrate. The double heterostructure is constituted with a GaInP active layer and AlGaInP clad layers sandwiching the GaInP active layer. A second conductivity type clad layer on the active layer has a mesa structure that reaches to the top face of the active layer. That is, the clad layer having the mesa structure is formed just above the active layer. A second conductivity type (AlₓGa₁₋ₓ)_{0.5}In_{0.5}P layer is formed on the side faces of the mesa structure and on the surface of the active layer on both sides of the mesa structures.

A self-pulsating semiconductor laser described in a Japanese Laid-Open Patent application (JP-A-Heisei, 11-220210) includes a first-conductivity type first clad layer, an active layer formed on the first clad layer, and a second-conductivity type second clad layer formed on the active layer. The second clad layer has a mesa portion, and a current constricting structure is provided on both sides of the mesa portion. The current constricting structure is made of a first conductivity type GaAs. Refractive index difference Δn in the lateral direction is within the range from 0.001 to 0.003. Further, a thickness d of the second clad layer on the outer side of the lateral waveguide is 400 nm or less. In this case, a lateral spread of the electric current injected into the active layer through the mesa portion at a normal temperature (25° C.) or a high temperature (60° C.) can be suppressed to be about the width of the bottom of the mesa portion.

### SUMMARY

The inventor of the present application has recognized that to control the “temperature dependency of self-pulsation” is important for achieving the stable self-pulsation in a semiconductor laser. The intensity of the self-pulsation depends on the volume of a saturable absorber region, and the volume is determined on the balance between the gain and the loss. That is, it is determined depending on the operation point on a gain curve (J-G curve) where the self-pulsation is actuated. The gain/loss balance is determined depending on a structure of the active layer, an overlap between the distribution of the optical waveguide and the distribution of the injected electric current that is injected to the active layer, and the extent in the loss of the optical waveguide path.

Under a low-temperature condition, the gain determined on the basis of a structure of the active layer is relatively large, and a lateral spread (diffusion) of the injected electric current is relatively small. Therefore, a self-pulsating operation occurs by the large gain and the loss that is in balance with the gain, so that the volume of the saturable absorber region tends to become large. However, when the gain determined depending on the structure of the active layer is too small or the lateral spread of the electric current is too narrow, the loss becomes excessive. Thus, the volume of the saturable absorber region becomes large, thereby weaken the intensity of the self-pulsation.

Under a high-temperature condition, the gain determined on the basis of the structure of the active layer is relatively small, and the lateral spread of the injected electric current is relatively large. Therefore, a self-pulsating operation occurs by the small gain and the loss that is in balance with the gain, so that the volume of the saturable absorber region tends to become small. However, when the gain determined depending on the structure of the active layer is too small so that the loss becomes excessive, or when the lateral spread of the electric current is too large so that the gain becomes excessive, the volume of the saturable absorber region becomes small. Therefore, the intensity of the self-pulsation is weakened.

As described above, the intensity of the self-pulsation depends on an operating temperature and an operating currents. However, such temperature dependency of the self-pulsation is not sufficiently considered in the above mentioned related techniques. Thus, even if a strong self-pulsation is obtained with an optimum gain within a specific temperature range, it is possible that the self-pulsation is weakened or stopped at other temperatures. This induces signal reproduction errors caused by optical feedback noises, which is not preferable in terms of the reliability of the products. Especially, it is required for a semiconductor laser used in an optical disk device to perform stable self-pulsation over a wide temperature range of about −10° C. to 75° C. It is difficult with the above mentioned related techniques to achieve the stable self-pulsation over such wide range of temperatures.

In one embodiment, the self-pulsating semiconductor laser includes; a lower clad layer formed on a semiconductor substrate; an active layer formed on the lower clad layer; a first upper clad layer formed on the active layer, wherein a thickness d of the first clad layer satisfies a relation 220 nm≦d≦450 nm; a second upper clad layer formed on the first upper clad layer and having a mesa structure; and a block layer including layers formed on both sides of the mesa structure, wherein bandgaps of the layers are larger than bandgaps of the active layer.

In another embodiment, a manufacturing method of a self-pulsating semiconductor laser includes: (a) forming a lower clad layer on a semiconductor substrate; (b) forming an active layer on the lower clad layer; (c) forming a first upper clad layer having a thickness within the range from 220 nm to 450 nm, on the active layer; (d) forming a second upper clad layer on the first upper clad layer; (e) etching the second upper clad layer to form a mesa structure; and (f) forming block layers on both side of the mesa structure. The bandgaps of the layers are larger than bandgaps of the active layers.

In further another embodiment of the manufacturing method of the self-pulsating semiconductor laser, the (f) forming includes: forming (AlₓGa₁₋ₓ)_{0.5}In_{0.5}P layers on both sides of the active layer.

In further another embodiment of the manufacturing method of the self-pulsation semiconductor laser, the (f) forming includes: (f1) forming (AlₓGa₁₋ₓ)_{0.5}In_{0.5}P layers on both sides of the active layer; and (f2) forming GaAs layer on each of the (AlₓGa₁₋ₓ)_{0.5}In_{0.5}P layers.

In further another embodiment, a manufacturing method of a self-pulsating semiconductor laser includes: (A) forming a first semiconductor laminated structure on a first region of a semiconductor substrate; and (B) forming a second semiconductor laminated structure on a second region of the semiconductor substrate. The (A) forming includes: (A1) forming a lower clad layer on the semiconductor substrate; (A2) forming an active layer on the lower clad layer; (A3) forming a first upper clad layer having a thickness within the range from n 220 nm to 450 nm on the active layer; (A4) forming a second upper clad layer on the first upper clad layer; and (A5) etching the second upper clad layer, the first upper clad layer, the active layer and the lower clad layer placed on an outside of the first region to generate the first semiconductor laminated structure. The (B) forming includes, (B1) forming another lower clad layer to cover the semiconductor substrate and the first semiconductor laminated structure; (B2) forming another active layer on the another lower clad layer; (B3) forming another first upper clad layer having a thickness within the range from 220 nm to 450 nm on the another active layer, (B4) forming another second upper clad layer on the another first upper clad layer; and (B5) etching the another second upper clad layer, the another first upper clad layer, the another active layer and the another lower clad layer placed on an outside of the second region to generate the second semiconductor laminated structure. The manufacturing method further includes: (C) etching each of the second upper clad layer and the another second upper clad layer to form a mesa structure, and (D) forming block layers to both sides of each of the mesa structures of the second upper clad layer and the another second upper clad layer, wherein a bandgap of each of the block layers is larger than a bandgap of the active layer.

In further another embodiment of the manufacturing method of the self-pulsating semiconductor laser, a material of the active layer and a material of the another active layer are different to each other.

In further another embodiment of the manufacturing method of the self-pulsating semiconductor laser, a distance between the semiconductor substrate and the active layer is substantially same to a distance between the semiconductor substrate and the another active layer.

In further another aspect of the manufacturing method of the self-pulsating semiconductor laser, the second upper clad layer and the another second upper clad layer are made of same material.

In further another aspect of the manufacturing method of the self-pulsating semiconductor laser, the (D) forming includes: (D1) forming (AlₓGa₁₋ₓ)_{0.5}In_{0.5}P layers on both side of the mesa structure in each of the first region and the second region.

In further another embodiment of the manufacturing method of the self-pulsating semiconductor laser, the (D) forming includes: (D1) forming (AlₓGa₁₋ₓ)_{0.5}In_{0.5}P layers on both side of the mesa structure in each of the first region and the second region; and (D2) forming a GaAs layer on each of the (AlₓGa₁₋ₓ)_{0.5}In_{0.5}P layers formed in the first and second region.

In the self-pulsating semiconductor laser mentioned above, the temperature dependency of the self-pulsation can be adequately taken into account. As a result, the stable self-pulsation can be maintained over a wide temperature range. Since optical feedback noises can be suppressed finely over the entire range of operating temperatures, the operation reliability can be improved. Further, an operating current is reduced, so that the long-term reliability can be improved as well.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view showing the structure of a self-pulsating semiconductor laser according to a first embodiment;

FIG. 2 is a graph showing the temperature dependency of an operating current;

FIG. 3 is a graph showing the temperature dependency of an interference index γ and a relative intensity noise RIN;

FIG. 4A is a graph showing the temperature dependency of the interference index γ regarding various values of parameter d;

FIG. 4B is a graph showing the temperature dependency of the relative intensity noise RIN regarding various values of parameter d;

FIG. 5A is a graph showing the temperature dependency of the interference index γ regarding various values of parameter Δn;

FIG. 5B is a graph showing the temperature dependency of the relative intensity noise RIN regarding the various values of parameter Δn;

FIG. 6A is a graph showing the temperature dependency of the interference index γ regarding various values of carrier density;

FIG. 6B is a graph showing the temperature dependency of the relative intensity noise RIN regarding the various values of carrier density;

FIG. 7A is a graph showing the temperature dependency of the interference index γ regarding various values of parameter W;

FIG. 7B is a graph showing the temperature dependency of the relative intensity noise RIN regarding various values of parameter W;

FIG. 8A is a sectional view showing a manufacturing step of the self-pulsating semiconductor laser according to a first embodiment;

FIG. 8B is a sectional view showing a manufacturing step of the self-pulsating semiconductor laser according to the first embodiment;

FIG. 8C is a sectional view showing a manufacturing step of the self-pulsating semiconductor laser according to the first embodiment;

FIG. 8D is a sectional view showing a manufacturing step of the self-pulsating semiconductor laser according to the first embodiment;

FIG. 9 is a sectional view showing a structure of a self-pulsating semiconductor laser according to a second embodiment;

FIG. 10 is a sectional view showing a structure of a self-pulsating semiconductor laser according to a third embodiment;

FIG. 11A is a sectional view showing a manufacturing step of a self-pulsating semiconductor laser according to a fourth embodiment;

FIG. 11B is a sectional view showing a manufacturing step of the self-pulsating semiconductor laser according to the fourth embodiment;

FIG. 11C is a sectional view showing a manufacturing step of the self-pulsating semiconductor laser according to the fourth embodiment;

FIG. 11D is a sectional view showing a manufacturing step of the self-pulsating semiconductor laser according to the fourth embodiment; and

FIG. 12 is a sectional view showing a manufacturing step of a self-pulsating semiconductor laser according to a fifth embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Referring to the accompanying drawings, self-pulsating semiconductor lasers of following embodiments are used, for example, as a light source of an optical disk device such as a DVD device.

### 1. First Embodiment

### 1-1. Structure

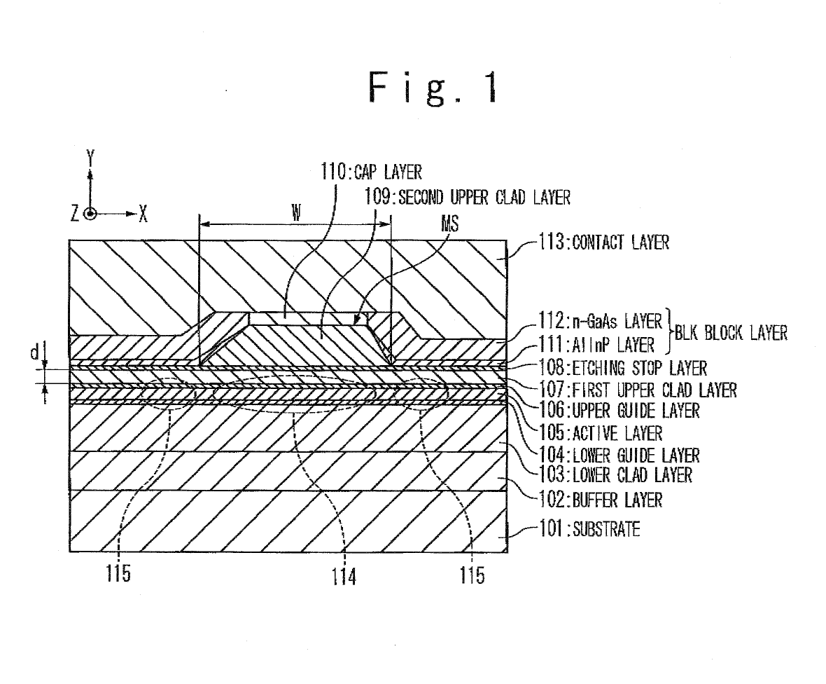

FIG. 1 is a sectional view showing a structure of a self-pulsating semiconductor laser according to a first embodiment of the present invention. In FIG. 1, the Z-direction is an axial direction of a cavity, and the X-direction (horizontal direction) is a direction that is orthogonal to the axial direction of the cavity and in parallel to a p-n junction face. The Y-direction is a direction that is orthogonal to the axial direction of the cavity and vertical to the pn-junction face. The standing waves that appear in the X, Y, and Z directions are called a horizontal transverse mode, a vertical transverse mode, and a longitudinal mode, respectively.

In FIG. 1, a first conductivity type buffer layer 102 for improving a crystalline property is formed on a first conductivity type semiconductor substrate 101. A “double heterostructure (DH)” is formed on the buffer layer 102. Specifically, an active layer 105 is formed on a first conductivity type lower clad layer 103 via a lower guide layer 104. A second conductivity type first upper clad layer 107 is formed on the active layer 105 via an upper guide layer 106. Further, a second conductivity type second upper clad layer 109 is formed on the first upper clad layer 107 via an etching stop layer 108. The second upper clad layer 109 has a “mesa structure MS (ridge structure)” that is formed in a stripe shape along the Z-direction.

Furthermore, a block layer BLK is formed on both sides of the mesa structure of the second upper clad layer 109. That is, the block layer BLK is formed to cover the side faces of the mesa structure MS and the etching stop layer 108 in a region where the mesa structure MS is not formed. As will be described later, the block layer BLK functions to constrict the injected electric current injected into the active layer 105 to the mesa structure. Further, the block layer BLK also functions to provide an optical waveguide (horizontal transverse mode) in the X-direction. In the present embodiment, the block layer BLK includes a layer which has a larger band gap than the active layer 105 and has a smaller refractive index than the second upper clad layer 109.

Further, the top face of the second upper clad layer 109 (mesa structure MS) is covered by a second conductivity type cap layer 110. A second conductivity type contact layer 113 is formed on the cap layer 110 and the block layer BLK.

The semiconductor laser element according to an embodiment of the present invention is constituted with a semiconductor laminated structure described above. The emission wavelength is, for example, about 650 nm. Examples of each layer that constitutes such semiconductor laser element will be described below. In the examples below, the first conductivity type is an n-type, and the second conductivity type is a p-type. Naturally, the n-type and the p-type may be reversed. Further, there are cases where (AlₓGa₁₋ₓ)_{0.5}In_{0.5}P is simply written as AlGaInP. In that case, Al composition ratio x is written within parentheses.

Semiconductor substrate 101: n-type GaAs

Buffer layer 102: n-type GaAs; thickness=650 nm; impurity concentration=5×10¹⁷ cm⁻³

Lower clad layer 103: n-type AlGaInP (x=0.7); thickness=1200 nm; impurity concentration=5×10¹⁷ cm⁻³

Lower guide layer 104: AlGaInP (x=0.45); thickness=30 nm

The band gap of the active layer 105 is smaller than those of the guide layer and the clad layer provided in surrounding region. The refractive index of the active layer 105 is larger than those of the guide layer and the clad layer provided in surrounding region. In the present embodiment, the active layer 105 has a multi-quantum well structure in which a plurality of quantum wells are laminated. Each of the wells is isolated by a respective barrier layer. Each well is formed with GaInP, and the thickness thereof is 5.0 nm. Each barrier layer is formed with AlGaInP (x=0.45), and the thickness thereof is 5.0 nm. The compression distortion applied to the wells is adjusted to achieve a desired oscillation wavelength at about 650 nm.

Upper guide layer 106: AlGaInP (x=0.45); thickness=30 nm

First upper clad layer 107: p-type AlGaInP (x=0.7); thickness d=300 nm; impurity concentration=

Etching stop layer 108: p-type AlGaInP (x=0.2); thickness=10 nm; impurity concentration 6×10¹⁷ cm⁻³

Second upper clad layer 109: p-type AlGaInP (x=0.7); thickness=1000 nm; impurity concentration=6×10¹⁷ cm⁻³; width W of the bottom of the mesa structure MS=4.0 μm

Cap layer 110: p-type GaAs; thickness=300 nm; impurity concentration=1.5×10¹⁸ cm⁻³

Contact layer 113: p-type GaAs; thickness=3000 nm; impurity concentration=2×10¹⁸ cm⁻³

The block layer BLK includes an n-type or undoped (AlₓGa₁₋ₓ)_{0.5}In_{0.5}P layer 111 and an n-type GaAs layer 112 formed thereon. The Al composition x may also be 1. In this case, the block layer BLK includes the n-type or undoped AlInP layer 111. The thickness of the AlInP layer 111 (or AlGaInP layer 111) is, for example, 150 nm. The thickness of the n-type GaAs layer 112 is 850 nm, for example, and the impurity density thereof is 3×10¹⁸ cm⁻³, for example. The band gap of the AlInP layer 111 (or AlGaInP layer 111) is larger than that of a light-emitting portion of the active layer 105, and the refractive index thereof is smaller than that of the second upper clad layer 109 (mesa structure MS). That is, the block layer BLK with a small optical absorption coefficient is formed.

In the structure above described, there is a difference generated in the refractive indexes in the X-direction due to the block layer BLK that is formed on the second upper clad layer 109 and on both sides thereof. That is, there is a difference generated in the refractive indexes between the portion that corresponds to the stripe-shaped mesa structure MS and the portion other than the mesa structure MS. This difference is called an effective index difference Δn. The effective refractive index difference Δn related to the optical waveguide in the X-direction depends also on the thickness d of the first upper clad layer 107. In the structure presented in the above-described example, the effective refractive index difference Δn related to the optical waveguide in the X-direction is about 2.0×10⁻³.

### 1-2. Operations and Operational Characteristics

Referring to FIG. 1, suppose that a forward bias is applied to the above-described double heterostructure. At this case, a reverse bias is applied between the block layer BLK (n-GaAs layer 112/n-ori-AlInP layer 111) and the p-type layer (p-AlGaInP layer 108/p-AlGaInP layer 107) provided thereunder. As a result, the electric current flows into the first upper clad layer 107 and the active layer 105 only from the second upper clad layer 109 (mesa structure MS). That is, the electric current is blocked by the block layer BLK, and constricted to the mesa structure MS. In this sense, the block layer BLK is considered to be functioning as a “current constriction mechanism”.

The mesa structure is formed so that an edge thereof is placed at the vicinity of the active layer 105, and the width where the electric current is injected in the active layer 105 nearly corresponds to the width W of the bottom face of the mesa structure MS. As a result, in the active layer 105, there is a gain (inverted distribution) generated only in the region that corresponds to the mesa structure MS. In FIG. 1, such region is shown as a gain region (active region) 114.

Further, regarding the optical waveguide, optical confinement (vertical transverse mode) in the Y-direction is achieved by the double heterostructure described above. Meanwhile, optical confinement (horizontal transverse mode) in the X-direction is achieved by the effective refractive index difference Δn described above. More specifically, the light is not confined inside the active layer 105, but it slightly leaks to the clad layer provided in the circumstance thereof due to the tunnel effect. The leaked light senses the block layer BLK with a relatively low refractive index, which is formed in the vicinity of the active layer 105. As a result, the above-described effective refractive index difference Δn is generated in the X-direction, and the light is confined. In this sense, the block layer BLK is also considered to be functioning as an “X-direction optical waveguide mechanism”.

In the active layer 105, the width of the optical waveguide region is larger than the width of the gain region 114. The difference between the optical waveguide region and the gain region 114, i.e. the optical waveguide region on the outer side of the gain region 114, functions as a “saturable absorber region 115”. The self-pulsation is achieved by the saturable absorber region 115. However, the extent of the self-pulsation depends on the volume of the saturable absorber region 115. The volume of the saturable absorber region 115 is determined depending on the size of the optical waveguide region and the size of the gain region 114. The size of the optical waveguide region is determined depending almost on the above-described effective refractive index difference Δn. Meanwhile, the size of the gain region 114 corresponds to the distribution width of the injected electric current that is injected into the active layer 105, and the distribution width of the injected electric current depends not only on the width W of the bottom of the mesa structure MS but also on the temperature.

Under a high-temperature condition, the distribution width of the injected electric current becomes relatively large, because the spread of the hole carrier in the X-direction (hereinafter, referred to as “lateral spread” in some cases) becomes large in the first upper clad layer 107 and the active layer 105 right under the mesa structure MS. Therefore, the gain region 114 becomes relatively large, so that a loss region that can function as the saturable absorber region 115 becomes relatively small. Inversely, under a low-temperature condition, the lateral spread of the injected electric current becomes small, and the gain region 114 becomes relatively small as well. Accordingly, the loss region that can function as the saturable absorber region 115 becomes relatively large.

As described, the volume of the loss region that can function as the saturable absorber region 115 changes depending on the temperature. Therefore, the self-pulsation also exhibits a temperature dependency. For example, when the volume of the loss region that can function as the saturable absorber region 115 becomes too large under a low-temperature condition, the self-pulsation is weakened due to the excessive loss. However, when the gain of the active layer itself is too large with respect to the loss, the gain becomes excessive inversely. In such a case, the self-pulsation may be weakened. In the meantime, under a high-temperature condition, when the volume of the loss region that can function as the saturable absorber region 115 becomes too small, the self-pulsation is weakened due to the excessive gain. However, when the gain of the active layer itself is too small with respect to the loss, the loss becomes excessive inversely. In such a case, the self-pulsation may be weakened. When the self-pulsation is weakened, the optical feedback noise becomes prominent. In order to improve the operation reliability of a semiconductor laser, it is important to design the laser by considering the temperature dependency, so that a stable self-pulsation can be maintained over a wide temperature range (at least −10° C. to 75° C.).

In order to achieve the stable self-pulsation, it is necessary to generate the oscillation itself stably. The oscillation is generated when the gain by an induced radiation exceeds a loss (transmission, absorption, dispersion, etc). Thus, it is preferable to reduce the loss as much as possible. The block layer BLK according to the present embodiment includes the AlInP layer 111 (or AlGaInP layer 111) whose an optical absorption coefficient in the oscillation wavelength region is small. Unlike the related techniques mentioned before, the block layer BLK is formed not only with the GaAs layer that has a characteristic of absorbing the light. As a result, the waveguide path loss is decreased, and the oscillation is enhanced. That is, the threshold current (a current value with which the oscillation is started) is decreased. Though the threshold current tends to increase in accordance with an increase in the temperature, the absolute value of the threshold current is small in this embodiment, so that it is possible to suppress weakening of the oscillation due to an insufficient gain, even under the high-temperature condition.

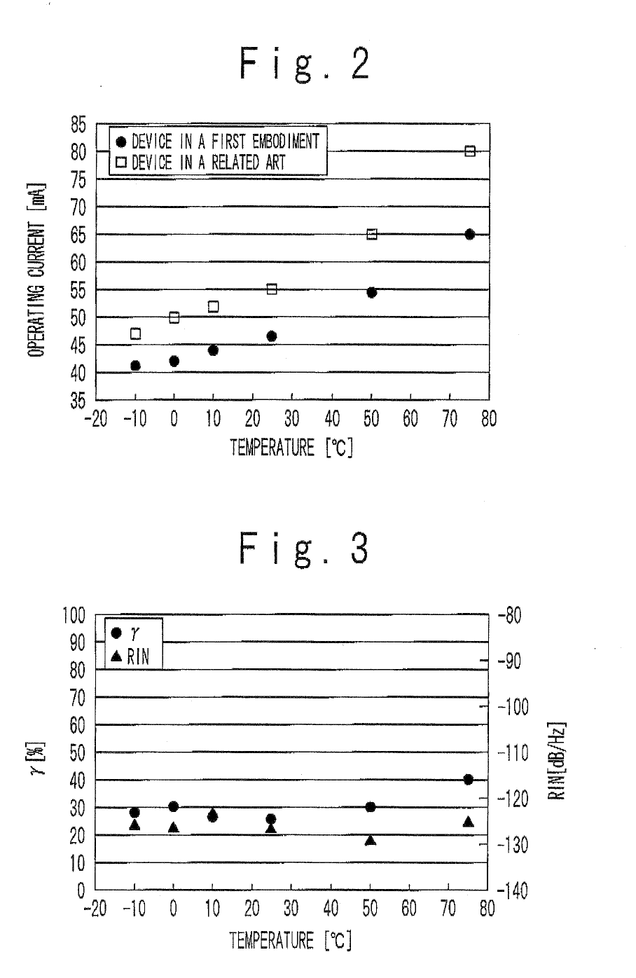

Further, since the waveguide path loss and the threshold current can be decreased, it is possible to obtain a desired optical output power with a still smaller operating current. FIG. 2 shows values of the operating current required for the optical output power of 4 mW regarding each of the semiconductor laser elements according to a related art and the present embodiment. The element of the present embodiment has a structure depicted in the above-described example. Meanwhile, the element of the related art includes a block layer that is constituted only with the n-type GaAs layer. As can be seen from FIG. 2, the operating current of the element according to the present embodiment is smaller than that of the related art under conditions of any temperatures. This is because the waveguide path loss as well as the threshold current thereof is decreased in the element of the present embodiment. Since it requires only a still smaller operating current, the slope efficiency is improved and the life of element can be extended as well. That is, the present invention is capable of improving an element performance and a long-term reliability. Due to a difference in the carrier overflows which becomes prominent under a high-temperature condition, the difference between operating currents becomes more significant as the temperature becomes higher. Therefore, the effects become more prominent under a high-temperature condition.

Next, the inventor of the present application investigated the temperature dependency of the self-pulsation. Specifically, the inventor of the present application studied a primary interference index γ and a temperature dependency of the relative intensity noise RIN for the optical feedback noise. When the strong self-pulsation is being obtained, the wavelength chirping of the longitudinal mode becomes large, and the values of γ and RIN are small. Inversely, when the self-pulsation is weakened, the values of γ and RIN are large. It is therefore possible to check whether or not a stable self-pulsation is being obtained by measuring the γ and RIN. As the references indicating the stable self-pulsation, it is required for γ to be 60% or less and RIN to be −110 dB/Hz or less.

FIG. 3 shows the temperature dependency of the interference index γ and the relative intensity noise RIN in a case of the above-described example (the thickness d of the first upper clad layer 107=300 nm). In this measurement experiment, the optical output power of the semiconductor laser is 4 mW. The optical path length (the distance between the optical disk and the laser element) is 34 mm. The feedback light amount is 1%. As can be seen from FIG. 3, both the interference index γ and the relative intensity noise RIN are maintained at low levels over a wide temperature range of −10° C. to 75° C. There is almost no change observed in the γ and RIN caused due to the temperature. This means that the self-pulsation is stably maintained over the wide temperature range without being weakened. That is, it is possible with the present invention to maintain the stable self-pulsation over the entire range of the required temperatures.

Furthermore, the inventor of the present application conducted an experiment, in which each sample having respective thickness d of the first upper clad layer is tested, and obtained the same kind or results for the samples. The thickness d affects the above-described effective refractive index difference Δn that determines the size of the optical waveguide region. When the thickness d becomes small, the effective refractive index difference Δn becomes large, thereby decreasing the size of the optical waveguide region. Meanwhile, when the thickness d becomes large, the effective refractive index difference Δn becomes small, thereby increasing the size of the optical waveguide region.

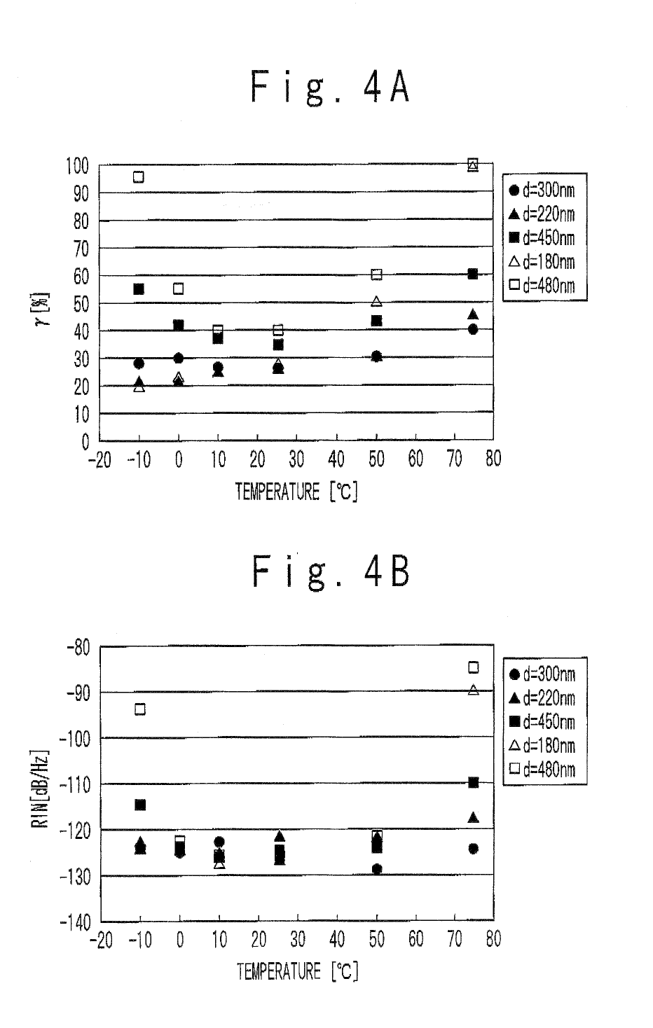

FIG. 4A shows the temperature dependency of the interference index γ regarding the various values of thickness d. FIG. 4B shows the temperature dependency of the relative intensity noise RIN regarding the various values of thickness d. As can be seen from FIGS. 4A and 4B, when the thickness d is 220 nm, 300 nm, or 450 nm, the γ and RIN are suppressed to 60% or a less and −110 dB/Hz or less, respectively, over the wide temperature range of −10° C. to 75° C. That is, the stable self-pulsation is maintained over a wide range of required temperatures.

However, in a case where the thickness d is 180 nm, the values of the γ and RIN are increased again at a high-temperature condition (75° C.). This means that the self-pulsation becomes weakened and the optical feedback noise is increased. In the case where the thickness d is 180 nm, the size of the optical waveguide region is decreased compared to the other cases. In addition, the lateral spread of the injected electric current becomes large under a high-temperature condition, and the gain region 114 becomes relatively large. This results in an excessive gain. Therefore, the volume of the saturable absorber region 115 becomes too small, so that the self-pulsation becomes weakened or stopped.

Further, in a case where the thickness d is 480 nm, the values of the γ and RIN are increased at a low-temperature condition (−10° C.) and at a high-temperature condition (75° C.). This also means that the self-pulsation becomes weakened and the optical feedback noise is increased. In the case where the thickness d is 480 nm, the size of the optical waveguide region is increased compared to the other cases. In addition, the lateral spread of the injected electric current becomes small under the low-temperature condition, and the gain region 114 becomes relatively small. This results in an excessive loss. Therefore, the volume of the saturable absorber region 115 becomes too small, so that the self-pulsation becomes weakened or stopped. Furthermore, at the high-temperature condition, the gain of the active layer 105 itself is decreased due to an influence of the carrier overflow. Therefore, the self-pulsation is also weakened or stopped because of the excessive loss.

As described above, from the view point of the temperature dependency of the volume of the saturable absorber region 115, the thickness d of the first upper clad layer 107 is preferable to be set as a value within the range from 220 nm to 450 nm.

Furthermore, the inventor of the present application conducted experiments by changing the other parameters of samples variously, and obtained same kind of results.

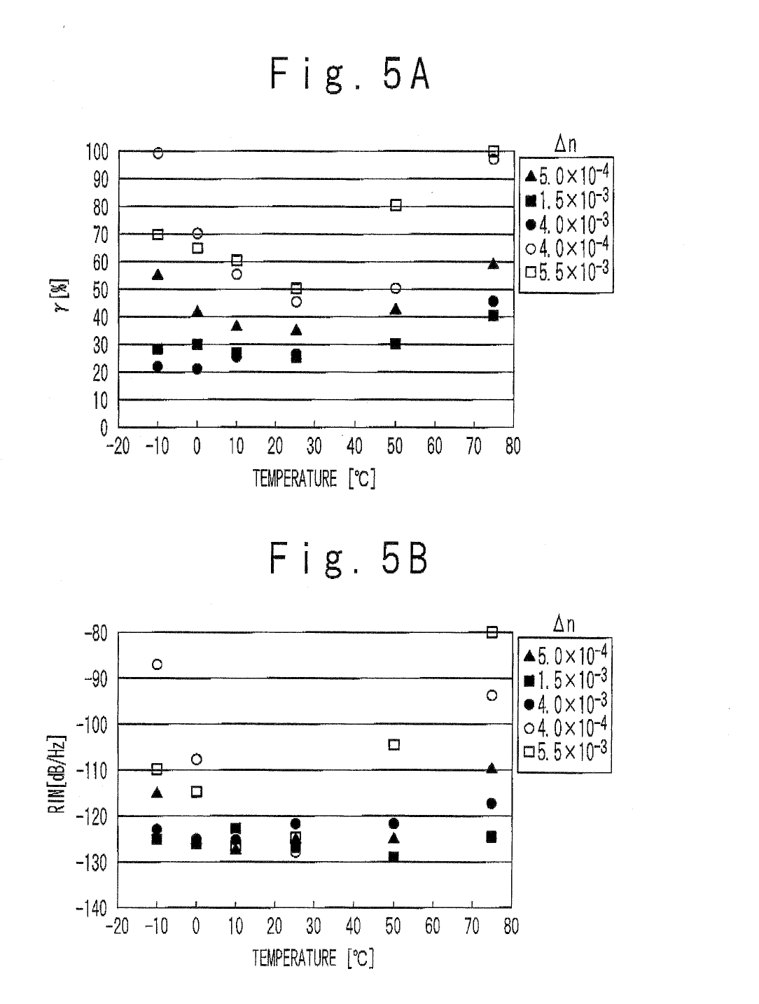

FIGS. 5A and 5B respectively show the temperature dependency of the interference index γ and that of the relative intensity noise RIN regarding the various values of effective refractive index difference Δn. As can be seen from FIGS. 5A and 5B, in a case where the effective refractive index difference Δn is within the range from 5.0×10⁻⁴ to 4.0×10⁻³, the values of the γ and RIN are suppressed to 60% or less and −110 dB/Hz or less, respectively, over a wide temperature range of −10° C. to 75° C. That is, the stable self-pulsation is maintained over a wide range of required temperatures. Meanwhile, when the effective refractive index difference Δn takes the values out of that range, the self-pulsation becomes weakened.

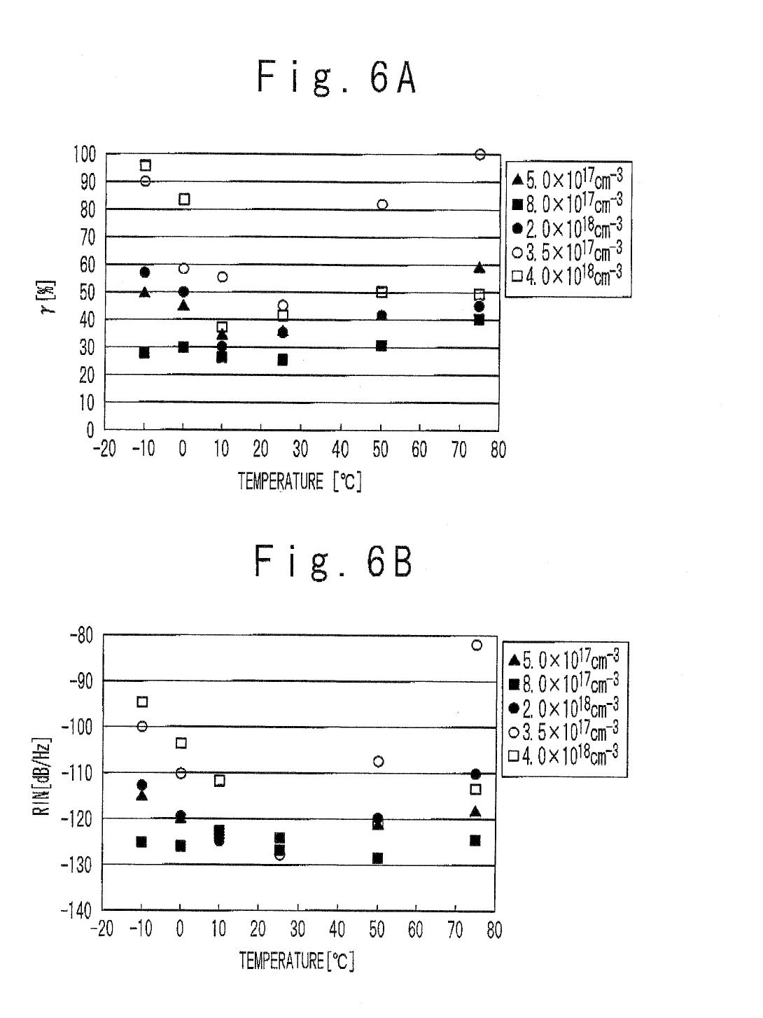

Thereafter, the influence of the carrier concentration (p-concentration) of the first upper clad layer 107 was investigated. FIGS. 6A and 68 respectively show the temperature dependency of the interference index γ and that of the relative intensity noise RIN regarding the various values of carrier concentration. As can be seen from FIGS. 6A and 6B, in a case where the carrier concentration of the first upper clad layer 107 is within the range from 5×10¹⁷ cm⁻³ to 2×10¹⁸ cm⁻³, the values of the γ and RIN are suppressed to 60% or less and −110 dB/Hz or less, respectively, over the wide temperature range of −10° C. to 75° C. That is, the stable self-pulsation is maintained over a wide range of required temperatures. Meanwhile, when the carrier concentration takes the values out of that range, the self-pulsation becomes weakened.

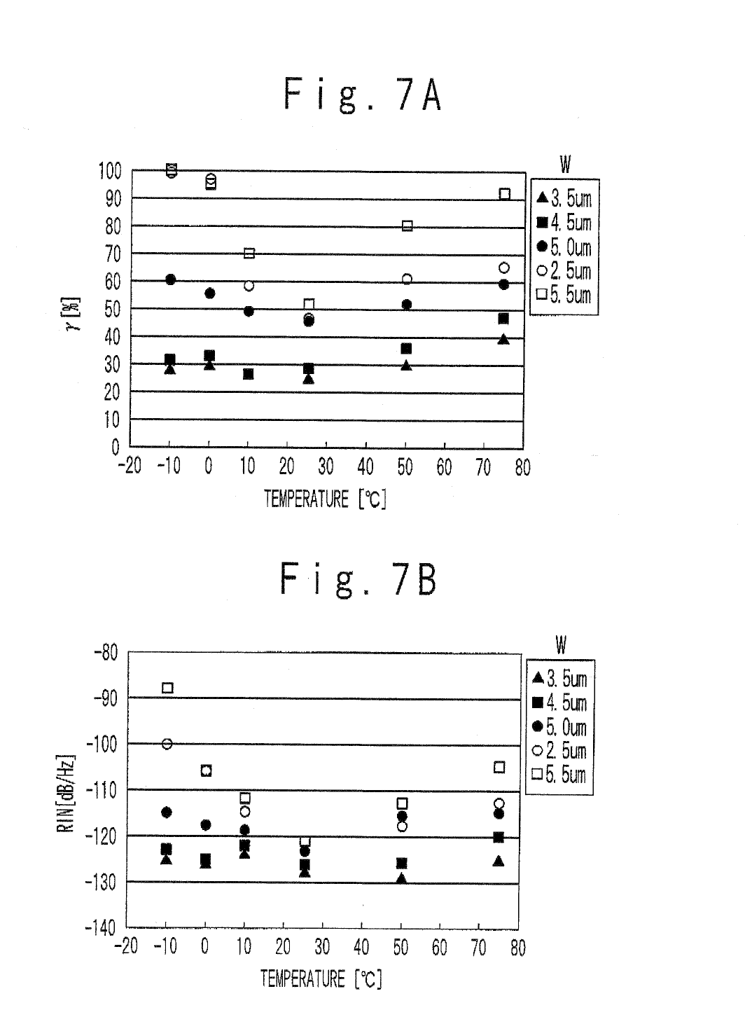

Then, investigated was the width W of the bottom of the mesa structure in the X-direction, which is one of the parameters that determine the distribution of the injected electric current. FIGS. 7A and 7B respectively show the temperature dependency of the interference index γ and that of the relative intensity noise RIN regarding the various values of width W. As can be seen from FIGS. 7A and 7B, in a case where the width W of a bottom of the mesa structure is within the range from 3.5 μm to 5.0 μm, the values of the γ and RIN are suppressed to 60% or less and −110 dB/Hz or less, respectively, over the wide temperature range of −10° C. to 75° C. That is, the stable self-pulsation is maintained over the wide range of required temperatures. Meanwhile, when the width W takes the values out of that range, the self-pulsation becomes weakened.

### 1-3. Manufacturing Method

Next, an example of a method for manufacturing the above-described semiconductor laser element will be described.

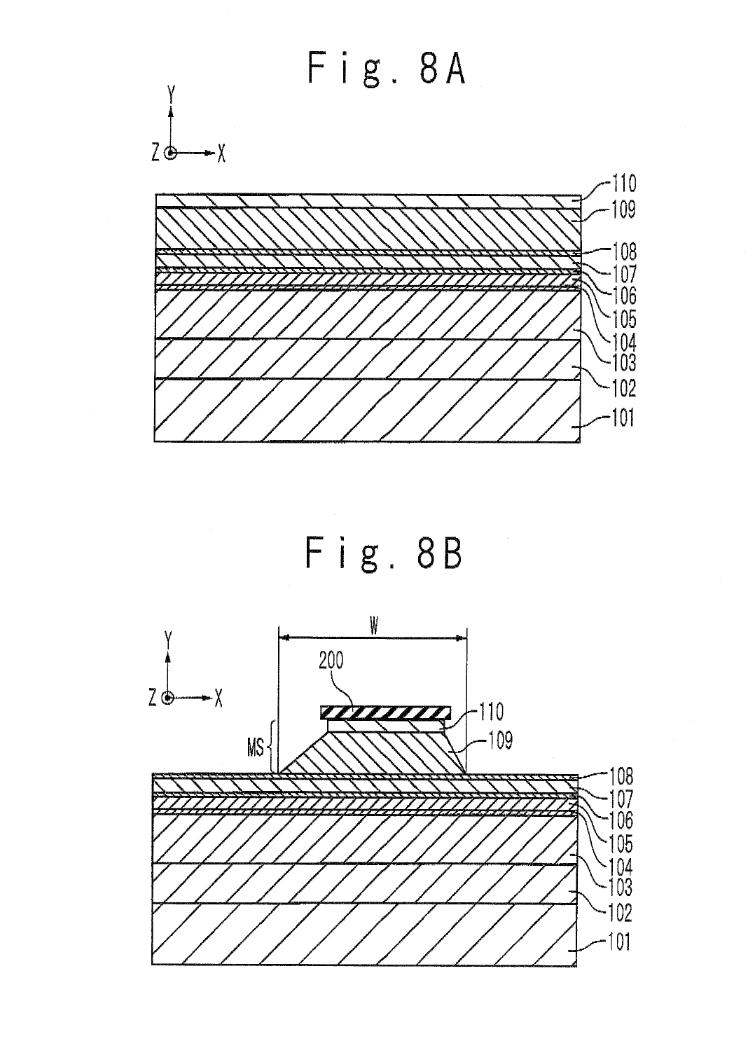

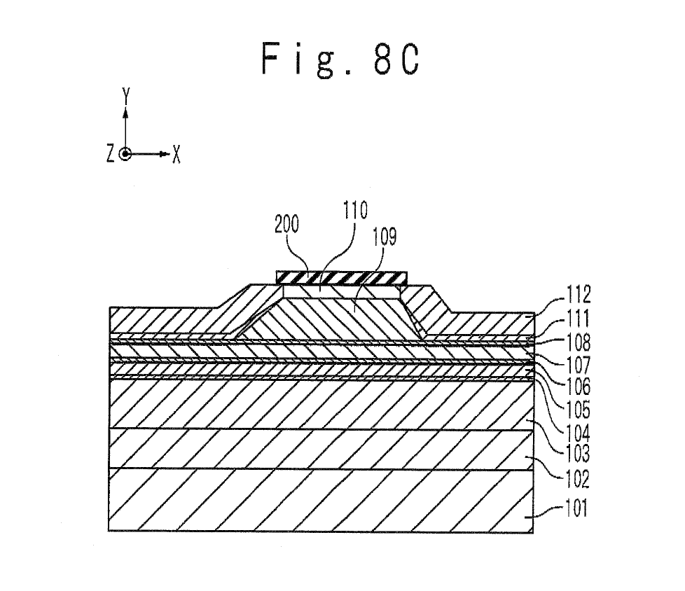

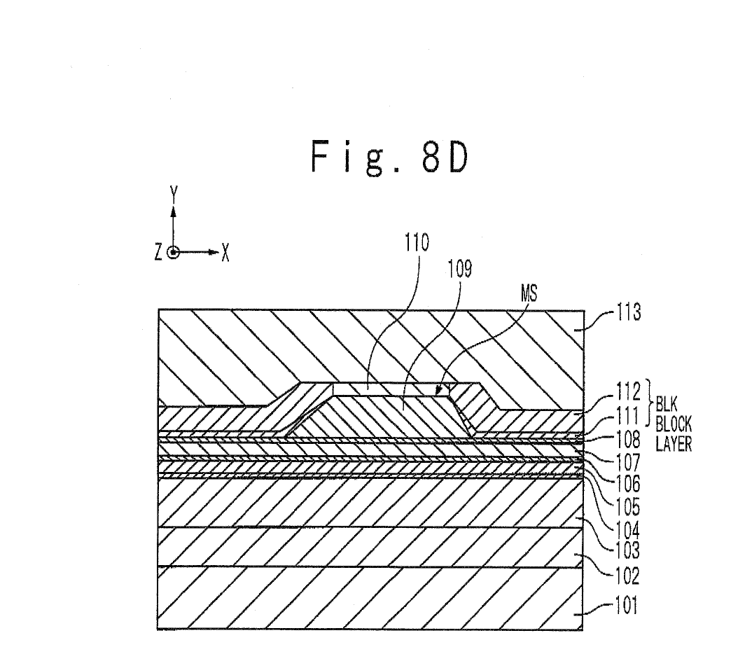

First, as shown in FIG. 8A, a semiconductor laminated structure is formed on a semiconductor substrate 101 by epitaxial growth. The semiconductor laminated structure is constituted with a buffer layer 102, a lower clad layer 103, a lower guide layer 104, an active layer 105, an upper guide layer 106, a first upper clad layer 107, an etching stop layer 108, a second clad layer 109, and a cap layer 110.

The lower clad layer 103 (n-type AlGaInP (x=0.7), thickness=1200 nm, the impurity concentration=5×10¹⁷ cm⁻²) is formed on the semiconductor substrate 101 (n-type GaAs) via the buffer layer 102 (n-type GaAs, thickness=650 nm, the impurity concentration=5×10¹⁷ cm⁻³). The multi-quantum well active layer 105 (well layer; GaInP, thickness=5.0 nm; barrier layer: AlGaInP (x=0.45), thickness=5.0 nm u) is formed on the lower clad layer 103 via the lower guide layer 104 (AlGaInP (x=0.45), thickness=30 nm). The compression distortion applied to the well layer is adjusted to have a desired oscillation wavelength at about 650 nm.

Furthermore, the first upper clad layer 107 (p-type AlGaInP (x=0.7)) is formed on the multi-quantum well active layer 105 via the upper guide layer 106 (AlGaInP (x=0.45), thickness=30 nm). The thickness d of the first upper clad layer 107 is within the range from 220 nm, to 450 nm, and the carrier concentration is within the range from 5×10¹⁷ cm⁻³ to 2×10¹⁸ cm⁻³. On the first upper clad layer 107, the second upper clad layer 109 (p-type AlGaInP (x=0.7), thickness=1000 nm, the impurity concentration=6×10¹⁷ cm⁻³) is formed via the etching stop layer 108 (p-type AlGaInP (x=0.2), thickness=10 nm, the impurity concentration=1.5×10¹⁷ cm⁻³). Further, the cap layer 110 (p-type CaAs, thickness=300 nm, is the impurity concentration 1.5×10¹⁸ cm⁻³) is formed on the second upper clad layer 109.

Then, an SiO₂ mask 200 is formed in a prescribed region on the cap layer 110 through thermal CVD, photolithography, and etching by hydrofluoric acid. Subsequently, as shown in FIG. 8B, wet-etching is performed by using the SiO₂ mask 200 until the etching stop layer 108 is exposed. As a result, the second upper clad layer 109 is processed to have a mesa structure MS. The width W of the bottom of the mesa structure MS in the X-direction is set to have a value within the range from 3.5 μm to 5.0 μm. The mesa structure MS may be formed through a combination of the dry-etching and wet-etching.

Then, as shown in FIG. 5C, a block layer BLK is formed on both sides of the mesa structure MS through selective epitaxial growth by using the SiO₂ mask 200. Specifically, an n-type or undoped AlGaInP layer 111 (thickness=150 nm) is formed to cover the side faces of the mesa structure MS and the exposed face of the etching stop layer 108. Then, an n-type GaAs layer 112 (thickness=850 nm, impurity concentration=3×10¹⁸ cm⁻³) is formed on the AlGaInP layer 111.

Next, after removing the SiO₂ mask 200, a contact layer 113 (p-type GaAs, thickness=3000 nm, the impurity concentration=2×10¹⁸ cm⁻³) is formed by an epitaxial growth as shown in FIG. 8D. Thereafter, a p-side electrode and an n-side electrode made of Ti/Pt/Au are formed, respectively, on both sides, and electrode alloying is performed at a temperature of 450° C. At last, the element is cut to have the length of 350 μm and the width of 250 μm, and coating is applied such that the reflectance of the front end face (light-emission face) becomes about 20% and that of the rear end face becomes about 70%.

In this manner described above, the semiconductor laser element according to the present embodiment can be manufactured. Through the above-described steps, the surface of the multi-quantum well active layer 105 is not to be exposed to the atmosphere. As a result, formation of non-luminescence center (dark defect) on a surface of the multi-quantum well active layer 105 can be prevented. Thus, it is possible to suppress weakening of the self-pulsation due to the insufficient gain of the multi-quantum well active layer 105 itself. Furthermore, the life of the element can be extended since the operating current can be decreased.

### 1-4. Effects

In a case that the block layer is formed only with an optical absorbing GaAs layer, the waveguide path loss becomes significant so that it is difficult to have a laser oscillation. As a result, the threshold current is increased, and the operating current becomes high as well. In particular, such problem is significant in the case of a semiconductor laser that includes an active layer made of a GaInP/AlGaInP type material, due to an influence of the carrier overflow that becomes prominent at high temperature.

The block layer BLK according to the present embodiment includes the AlGaInP layer that has a larger band gap than that of the active layer 105. That is, there is formed a block layer BLK whose optical absorption coefficient in the oscillation wavelength region is small. Because of such block layer BLK, the waveguide path loss is decreased, and oscillation can be easily generated. As a result, the threshold current is decreased, so that the slope efficiency is improved and the operating current can be decreased. The threshold current tends to increase in accordance with an increase in the temperature. However, the absolute value of the threshold current is decreased, so that it is possible to suppress weakening of the self-pulsation due to an insufficient gain even under a high-temperature condition. Further, since the threshold current can be decreased and the slope efficiency is improved, it is possible to obtain a desired optical output power with a still smaller operating current (see FIG. 2). Furthermore, since the operating current is decreased, the life of the element can be extended. That is, it is possible with the embodiment to improve the element performance and the long-term reliability.

Furthermore, in the present embodiment, the thickness d of the first upper clad layer 107 is designed to have a value within the range from 220 nm to 450 nm. In this case, the interference index γ and the relative intensity noise RIN can be suppressed to sufficiently low values over a wide temperature range (−10° C. to 75° C.) as shown in FIGS. 4A and 4B. This means that the self-pulsation is stably maintained over the wide temperature range without being weakened. As described, it is possible with the present embodiment to achieve a fine signal reproduction over the entire temperature range (−10° C. to 75° C.) which is required as a light source of the optical disk device. The optical feedback noise can be suppressed sufficiently, so that the reliability of the semiconductor laser can be improved.

With the above-described structure, “the loss by the saturable absorber layer” and “the gain of the active layer itself” which may vary depending on temperature can be balanced properly over a wide temperature range. Thus, a gain characteristic suited for the self-pulsation can be achieved over a wide operating temperature range. Such oscillation characteristic can be achieved with a low threshold current and high slope efficiency, so that an element with an excellent long-term reliability can be obtained. Furthermore, it is possible with the above-described structure to decrease the in-plane variations in the temperature dependency of the self-pulsation intensity and to obtain a high reproducibility. This enables a manufacture yield to be maintained high and stable, thereby improving the productivity.

### 2. Second Embodiment

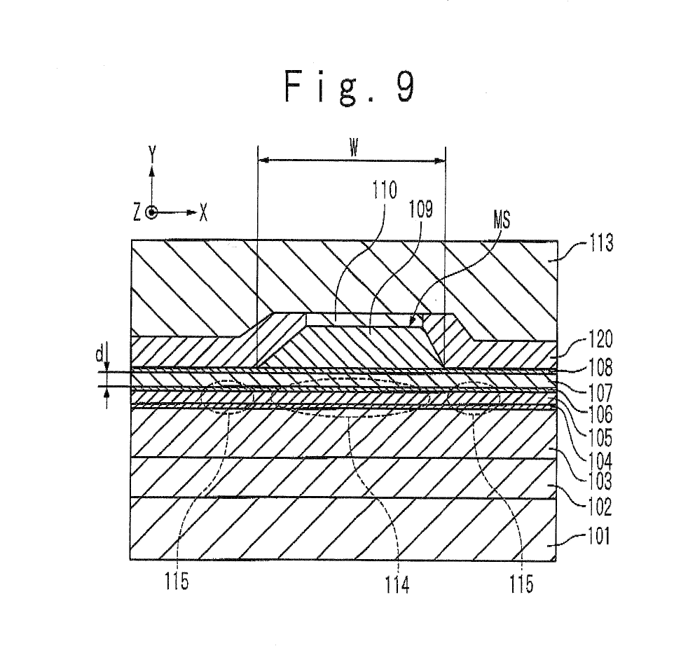

FIG. 9 is a sectional view showing the structure of a self-pulsating semiconductor laser according to a second embodiment of the present invention. In FIG. 9, the same reference numerals are applied to the structure elements that are same as those of FIG. 1, and redundant explanations are omitted as appropriate.

The block layer BLK according to the present embodiment is constituted only with a first-conductive (AlₓGa₁₋ₓ)_{0.5}In_{0.5}P layer 120 without an GaAs layer. For example, the block layer BLK includes an n-type AlInP layer 120 (x=1). The thickness of the n-type AlInP layer 120 is 1000 nm, for example, and the impurity density is 3×10¹⁸ cm⁻³, for example. With such structure, it is possible to obtain the same effects as those of the first embodiment. The manufacturing method of the semiconductor laser element according to the present embodiment is the same as that of the first embodiment.

### 3. Third Embodiment

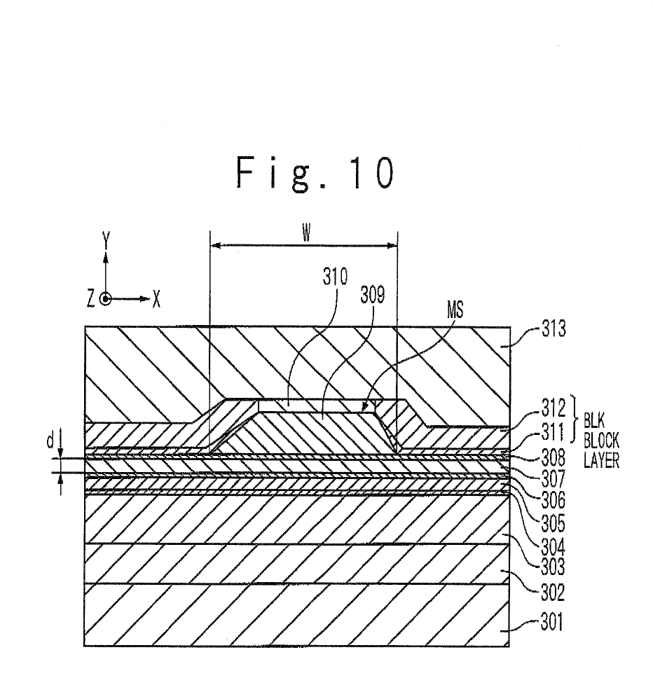

In the case presented in the first embodiment, the semiconductor laminated structure on the semiconductor substrate 101 is formed with a GaInP/AlGaInP type material, and the emission wavelength is about 650 nm. The present invention is also effective for a self-pulsating semiconductor laser in which the semiconductor laminated structure is formed with a GaAs/AlGaAs type material, and the emission wavelength is about 780 nm. FIG. 10 shows the structure of such self-pulsating semiconductor laser. Explanations that overlap with those of the above-described embodiments are omitted as appropriate. Examples of each layer shown in FIG. 10 will be explained below.

Semiconductor substrate 301: n-type GaAs

Buffer layer 302: n-type GaAs; thickness=650 nm; impurity concentration=5×10¹⁷ cm⁻³

Lower clad layer 303: n-type AlGaAs (x=0.5); thickness=1200 nm impurity concentration=1×10¹⁸ cm⁻³

Lower guide layer 304: AlGaAs (x=0.34); thickness=80 nm

Multi-quantum well active layer 305: well layer (AlGaAs (x=0.05), thickness=4.8 nm); barrier layer (AlGaAs (x=0.34), thickness=5.0 nm)

Upper guide layer 306: AlGaAs (x=0.34); thickness=80 nm

First upper clad layer 307: p-type AlGaAs (x=0.5); thickness d=250 nm; impurity concentration=5×17 cm⁻³

Etching stop layer 308: p-type AlGaAs (x=0.2); thickness=10 nm; impurity concentration=5×10¹⁷ cm⁻³

Second upper clad layer 309: p-type AlGaAs (x=0.5); thickness=1000 nm; impurity concentration=5×10¹⁷ cm⁻³; width W of the bottom of the mesa structure MS=4.5 μm

Cap layer 310: p-type GaAs; thickness=300 nm; impurity concentration=1.5×10¹⁸ cm⁻³

Contact layer 313: p-type GaAs; thickness 3000 nm n; impurity concentration=2×10¹⁸ cm⁻³

Like the first embodiment, the block layer BLK includes an n-type or undoped AlInP layer 311 (or AlGaInP layer 311) and an n-type GaAs layer 312 formed thereon. The thickness of the AlInP layer 311 (or AlGaInP layer 311) is 150 nm, for example. The thickness of the n-type GaAs layer 312 is 850 nm, for example, and the impurity density thereof is 3×10¹⁸ cm⁻³, for example. Alternatively, the block layer BLK may be constituted only with the n-type AlGaInP layer as in the second embodiment. With the above-described structures, the effective refractive index difference Δn in the X-direction becomes about 2.5×10⁻³.

With the structure according to the present embodiment, it is also possible to obtain same effects as those of the first embodiment. That is, the stable self-pulsation can be maintained over a wide temperature range through setting the parameter d appropriately. Further, the semiconductor laser element according to the present embodiment can be manufactured by the method same as that of the first embodiment.

### 4. Fourth Embodiment

In the self-pulsating semiconductor laser according to the present invention, a plurality of light sources having different emission wavelengths may be integrated monolithically. For example, a first light source which is presented in the first embodiment (whose emission wavelength is about 650 nm) and a second light source which is presented in the third embodiment (whose emission wavelength is about 280 nm) may be formed monolithically on a semiconductor substrate. In this case, the structure shown in FIG. 1 and the structure shown in FIG. 10 are formed as a monolithic structure on a single chip. An example of a method for forming such monolithic structure will be described below. Explanations that overlap with those of the above-described embodiments are omitted as appropriate.

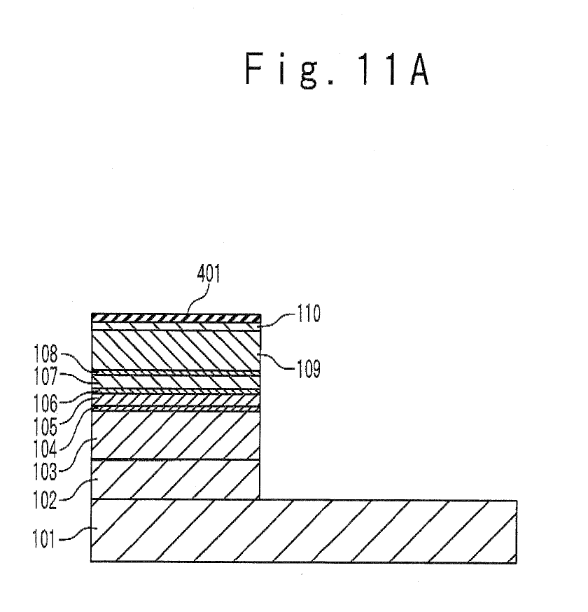

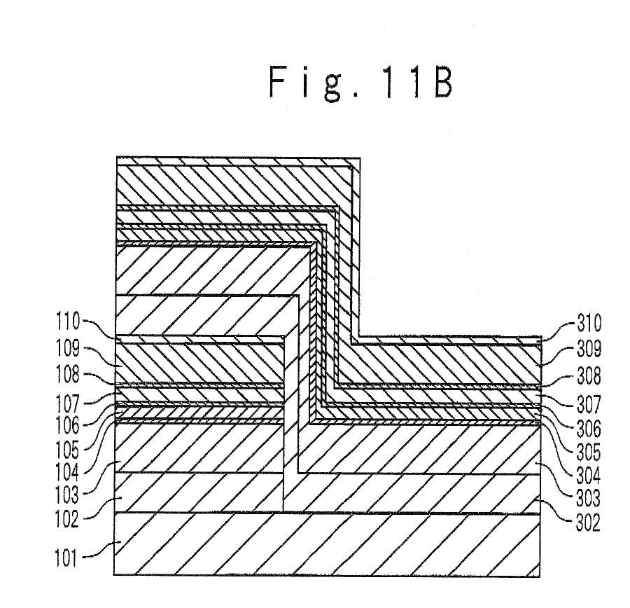

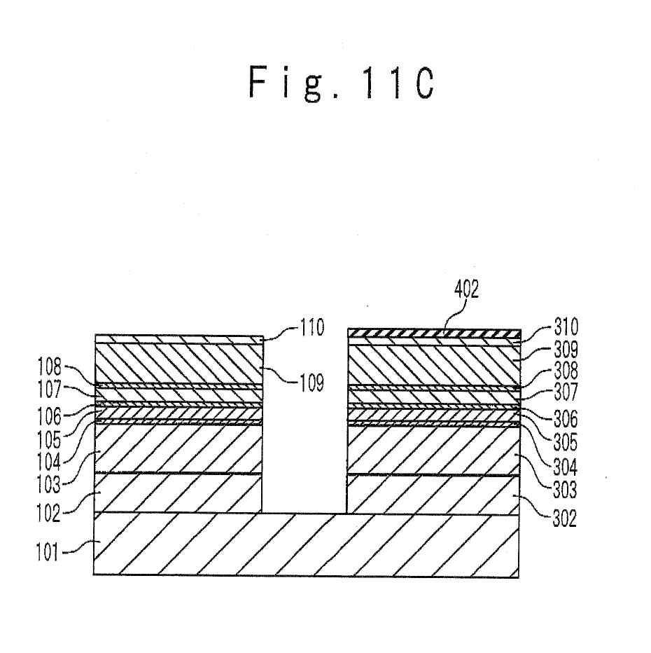

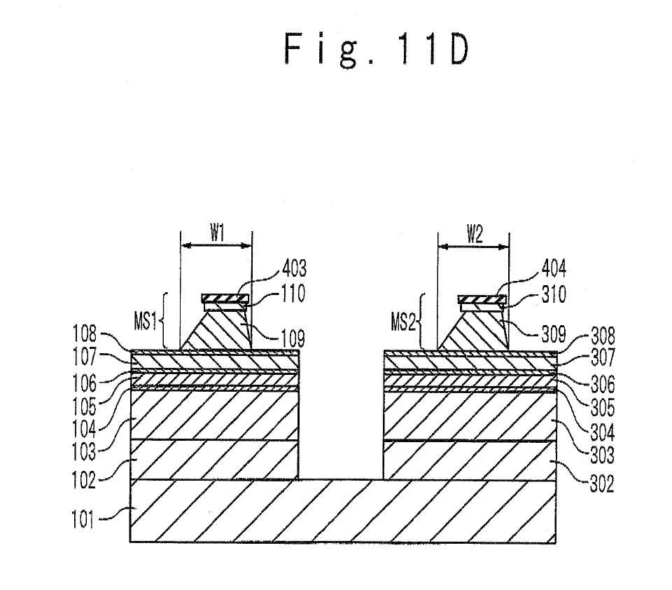

First, as shown in FIG. 11A, each of the semiconductor layers 102-110 described above is formed in order on the semiconductor substrate 101. Then, an SiC₂ mask 401 is formed by a photolithography technique in a first region where the first light source having an emission wavelength of 650 nm is formed. Subsequently, the semiconductor layers 102-110 in the regions other than the first region are removed through the wet-etching or the dry-etching by using the SiO₂ mask 401. As a result, a first semiconductor laminated structure as the prototype for the first light source is formed on the semiconductor substrate 101 in the first region.

Then, after removing the SiO₂ mask 401, each of the above-described semiconductor layers 302-310 is formed in order as shown in FIG. 11B. That is, each of the semiconductor layers 302-310 is formed over the entire surface to cover the semiconductor substrate 101 and the first semiconductor laminated structure. At this point, the thickness of the buffer layer 302 and the lower clad layer 303 is adjusted as appropriate so that the heights of the emission points of two light sources is same. As a result, the distance between the semiconductor substrate 101 and the active layer 105 of the first light source becomes substantially equal to the distance between the semiconductor substrate 101 and the active layer 305 of the second light source.

Then, as shown in FIG. 11C, an SiO₂ mask 402 is formed by the photolithography technique in a second region where the second light source having the emission wavelength of 780 nm is formed. Subsequently, the semiconductor layers 302-310 in the regions other than the second region are removed through the wet-etching or the dry-etching by using the SiO₂ mask 402. As a result, a second semiconductor laminated structure as the prototype for the second light source is formed on the semiconductor substrate 101 in the second region. The first semiconductor laminated structure and the second semiconductor laminated structure may be formed in the inverse order.

Then, as shown in FIG. 11D, SiO₂ masks 403 and 404 are formed respectively in a prescribed region of the cap layers 110 and 310. Subsequently, the wet-etching is performed by using the SiO₂ masks 403 and 404 until each of the etching stop layers 108 and 308 is exposed. As a result, mesa structures MS1 and MS2 are formed at once in each of the first and second regions. The width W1 and W2 of the bottoms of the mesa structures MS1 and MS2 are 4.0 μm and 4.5 μm, respectively. The mesa structures MS1 and MS2 may be formed through a combination of the dry-etching and the wet-etching.

Thereafter, the block layer BLK is formed on both sides of each mesa structure MS1 and mesa structure MS2 in each of the first and second regions. The method for forming each block layer BLK is the same as that of the above-described embodiments. In this manner described above, the first light source and the second light source having different emission wavelengths are formed monolithically on the semiconductor substrate 101. The effective refractive index difference Δn is about 2.0×10⁻³ for the first light source (emission wavelength=650 nm) and about 2.5×10⁻³ for the second light source (emission wavelength=780 nm).

With the structure according to the present embodiment, it is also possible to obtain the same effects as those of the above-described embodiments. That is, the stable self-pulsation can be maintained over the wide temperature range for each of the first and second light sources. Further, the operating current can be reduced for each of the first and second light sources.

### 5. Fifth Embodiment

In the fourth embodiment, material of the second upper clad layer 109 is a p-type AlGaInP (x=0.7), and that of the second upper clad layer 309 is a p-type AlGaAs (x=0.5). Even though the different materials are used for those layers, the mesa structures MS1 and MS2 can be formed at once by a proper etching process. In cases where such proper etching process cannot be employed, it is preferable to form the second upper clad layers with a same material for all light sources.

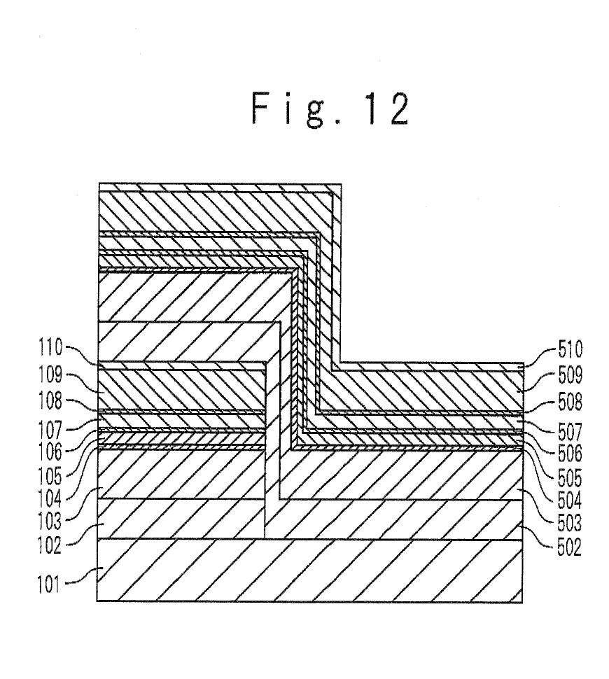

For example, the p-type AlGaInP (x=0.7) that is the same material as that of the first region may be used for the second upper clad layer in the second region. A cross sectional view corresponding to a part of manufacturing steps in this case is shown in FIG. 12. FIG. 12 corresponds to the step shown in FIG. 11B used for describing the fourth embodiment. As shown in FIG. 12, semiconductor layers 502-510 are formed instead of the semiconductor layers 302-310. Examples of each layer in the structure shown in FIG. 12 will be provided below.

Buffer layer 502: n-type GaAs; thickness=650 nm; impurity concentration=5×10¹⁷ cm⁻³

Lower clad layer 503: n-type AlGaAs (x=0.65); thickness=1200 nm; impurity concentration=1×10¹⁸ cm⁻³

Lower guide layer 504: AlGaAs (x=0.4); thickness=5 nm

Multi-quantum well active layer 505: well layer (AlGaAs (x=0.04), thickness=4.5 nm); barrier layer (AlGaAs (x=0.4), thickness=5.0 nm)

Upper guide layer 506; AlGaAs (x=0.4); thickness=5 nm

First upper clad layer 507: p-type AlGaAs (x=0.65); thickness d=250 nm; impurity concentration=5×10¹⁷ cm⁻³

Etching stop layer 508: p-type AlGaAs (x=0.2); thickness=10 nm; impurity concentration 6×10¹⁷ cm⁻³

Second upper clad layer 509: p-type AlGaInP (x=0.7); thickness=1000 nm, impurity concentration=6×10¹⁷ cm⁻³;

Cap layer 510: p-type GaAs; thickness=300 nm; impurity concentration=1.5×10¹⁸ cm⁻³

As described above, the p-type AlGaInP (x=0.7) that is the same material as that of the first region is used for the second upper clad layer 509 in the second region. As a result, the mesa structures MS1 and MS2 can be formed by etching the first and second regions at the same time. Other manufacturing steps are the same as those described in the fourth embodiment. It is also possible with the present embodiment to obtain the same effects as those of the fourth embodiment.

### 6. CONCLUSION

As described above, the temperature dependency of the self-pulsation in a self-pulsating semiconductor laser can be fully considered in embodiments of the present invention. As a result, the stable self-pulsation can be maintained over a wide temperature range. Since the optical feedback noise can be suppressed finely over the entire range of the required temperatures, the operation reliability can be improved. Further, the operating current can be decreased, so that the long-term reliability can be improved. The present invention can be applied not only to the self-pulsating semiconductor lasers of GaInP/AlGaInP, GaAs/AlGaAs types but also to the other types of self-pulsating semiconductor laser such as InGaAsP/InP, GaN, ZnSe type.

It is apparent that the present invention is not limited to the above embodiments, but may be modified and changed without departing from the scope and spirit of the invention.

What is claimed is:

1. A self-pulsating semiconductor laser comprising:
a lower clad layer formed on a semiconductor substrate;
an active layer formed on the lower clad layer;
a first upper clad layer formed on the active layer, wherein a thickness d of the first clad layer satisfies a relation 220 nm≦d≦450 nm;
a second upper clad layer formed on the first upper clad layer and having a mesa structure; and
a block layer including layers formed on both sides of the mesa structure, wherein bandgaps of the layers are larger than bandgaps of the active layer.

2. The self-pulsating semiconductor laser according to claim 1, wherein a saturable absorber region is formed in the active layer and outside of a gain region in the active layer.

3. The self-pulsating semiconductor laser according to claim 1, wherein the block layer includes (AlₓGa₁₋ₓ)_{0.5}In_{0.5}P layer.

4. The self-pulsating semiconductor laser according to claim 1, wherein the block layer includes (AlₓGa₁₋ₓ)_{0.5}In_{0.5}P layer and GaAs layer.

5. The self-pulsating semiconductor laser according to claim 4, wherein The GaAs layer is formed on the (AlₓGa₁₋ₓ)_{0.5}In_{0.5}P layer.

6. The self-pulsating semiconductor laser according to claim 1, wherein an effective refractive index difference Δn between a region corresponding to the mesa structure in a direction normal to an axis of a cavity and parallel to a pn junction surface and a region corresponding to a place outside of the mesa structure in the direction satisfies a relation 5×10⁻⁴≦Δn≦4×10⁻³ cm⁻³.

7. The self-pulsating semiconductor laser according to claim 1, wherein a carrier concentration of the first upper clad layer is within a range of 5×10¹⁷ cm⁻³ to 2×10¹⁸ cm⁻³.

8. The self-pulsating semiconductor laser according to claim 1, wherein a width of a bottom of the mesa structure in a direction normal to an axis of a cavity of the self-pulsating laser and parallel to a pn junction surface of the self-pulsating laser is within a range from 3.5 μm to 5.0 μm.

9. The self-pulsating semiconductor laser according to claim 1, wherein a first light source and a second light source wavelength of which are different to each other are monolithically formed on the semiconductor substrate, and
each of the first light source and the second light source has the lower clad layer, the active layer, the first upper clad layer, the second upper clad layer and the block layer.

10. The self-pulsating semiconductor laser according to claim 9, wherein the second upper clad layer of the first light source and the second upper clad layer of the second light source are made of same material.
